(19) United States
(12) Patent Application Publication
(10) Pub. No.: US 2024/0231229 A9
(43) Pub. Date: Jul. 11, 2024

(54) COMPOSITION FOR PREPARING TOP ANTIREFLECTION FILM, TOP ANTIREFLECTION FILM AND FLUORINE-CONTAINING COMPOSITION

(71) Applicant: GANSU HUALONG SEMICONDUCTOR MATERIAL TECHNOLOGY CO., LTD., Baiyin City (CN)

(72) Inventor: Yongbin LI, Baiyin City (CN)

(21) Appl. No.: 18/548,024

(22) PCT Filed: Dec. 30, 2022
(86) PCT No.: PCT/CN2022/144187

§ 371 Date: Aug. 25, 2023

(30) Foreign Application Priority Data
Jan. 7, 2022 (CN) 202210011889.8

(51) Int. Cl. G03F 7/09; C09D 171/00

(52) U.S. Cl. CPC G03F 7/091; C09D 171/00

(57) ABSTRACT

A composition for preparing a top antireflection film for photoresist includes a fluorine-containing composition, an alkali, an acid, and a surfactant. The fluorine-containing composition includes a fluorine-containing polymer. The fluorine-containing composition includes fluorine-containing polymers respectively including n=1, 2, 3, 4 and ≥5 fluorine-containing polyether groups, the content of the fluorine-containing polymers is 0-10 wt %, 30-68 wt %, 32-60 wt %, 0-15 wt %, and 0-8 wt %, respectively; the content of the fluorine-containing composition in the composition for preparing the top antireflection film for photoresist is 1-15 wt %. The antireflection film can avoid light scattering and standing wave effect, and the pH of the composition and the PH of photoresist are well matched, which improves the problem of the porosity and uniformity of the film surface and a large difference in thickness between a center point and the edge after coating, improving the yield of the photolithographic process.

### TECHNICAL FIELD

The present invention relates to the technical field of advanced optical materials, and in particular to a composition for preparing a top antireflection film for photoresist, a top antireflection film for photoresist, and a fluorine-containing composition.

### BACKGROUND

Lithography technology is a method for transferring a semiconductor circuit pattern on a photomask to a silicon wafer, a photomask template is irradiated through laser or electron beams, so that photosensitive substances on the wafer change the material properties due to photosensitivity, thereby completing the process of pattern transfer, the existing lithography technology has the technical problem of light scattering, resulting in low dimensional accuracy of photoresist imaging. At present, the mainstream solution is to add a top antireflection film of fluorine-containing compounds with low refractive index and high transmittance before and after photoresist coating, which reduces the interference of light in the photoresist and prevents the change of photolithographic line width due to the change of photoresist thickness.

The inventor of the present invention found that the current lithographic antireflection film uses many types of fluorine-containing compounds, such as perfluorooctanoic acid, perfluorooctane sulfonic acid, and fluorine-containing polymers, which are fluorine-containing acyclic small molecule materials. Patent application CN1666154A discloses an antireflection coating composition, which is mainly composed of an alkaline-soluble fluorine-containing polymer-[CF₂CF(ORfCOOH)]-(Rf represents a linear or branched perfluoroalkyl group, which may include ether oxygen atoms), an acid, an amine, and a solvent. Patent application CN101568991A discloses a composition for forming an antireflection film, which includes a specific naphthalene compound, a polymer (—[CF₂CF(ORfCOOH)]—), and a solvent. Patent application JP10069091A discloses a composition for a top antireflection film, including a perfluoroalkyl ether carboxylic acid (F—[CF(CF₃)CF₂—O]ₘ—CF(CF₃)COOH, where m is an integer of 1-10, preferably an integer of 2-4), an homopolymer or copolymer of N-vinylpyrrolidone, and an aqueous solution of at least one amino acid derivative. Patent application TW200928594A discloses a composition for a top antireflection film, including a fluorine-containing compound of the general formula Rf—O—[CF(CF₃)CF₂—O]ₘ—CF(CF₃)COOH (where Rf is a partial or perfluorosubstituted alkyl group, and m is an integer of 0-10), an amine compound, and a water-soluble polymer.

However, the fluorine-containing compound has the problems of degradation and accumulation in human body. It has been anticipated in the semiconductor industry to reduce the coating amount of film-forming compositions in order to minimize the impact on the environment. Due to the health and environmental problems caused by the low degradation and accumulation of fluorine-containing compounds in the human body, when forming a top antireflection film, the amount of composition of the coated fluorine-containing compound is reduced. Chinese patent application CN101849209A discloses a fluorine-containing acyclic composition for forming a top antireflection film, including at least one fluorine-containing compound and a quaternary ammonium compound, and non-mandatory selected water-soluble polymers, acids, surfactants and aqueous solvents. The composition for forming a top antireflection film may exhibit the same level of function as the traditional composition for forming a top antireflection film when coated in less amounts. Chinese patent application CN112034683B discloses a fluorine-containing acyclic composition for a top antireflection layer, in order to make the top antireflection layer meet the thickness requirements of 40-45 nm, it has the problems of large usage and large differences in thickness between the center point and edge after coating, and T-shaped tops.

Although the composition for a top antireflection film in the prior art is used for forming a top antireflection film for lithography, there are still certain deficiencies in terms of processability, film-forming property, refractive index, coating amount or raw material cost.

### SUMMARY

For the technical problems in the prior art, an objective of the present invention is to provide a composition for preparing a top antireflection film for photoresist, a top antireflection film for photoresist, and a fluorine-containing composition. The composition for preparing a top antireflection film has a pH value matching the pH value of the photoresist, has good stability and film-forming property, and can be coated in less amount for preparing the top antireflection film of a lower refractive index, thereby reducing the pattern defects that may occur during the lithography process, improving the quality of the lithographic pattern, and improving the problem of large differences in thickness between the center point and edge after coating, while adding an appropriate amount of acid to the top antireflection layer system can inhibit H+ in the photoresist diffusing to the antireflection film, so as to avoid the problem of forming a T-shaped top.

The objective of the present invention is implemented through the following technical solution:

The composition for preparing a top antireflection film for photoresist includes:

A) a fluorine-containing composition which contains a fluorine-containing polymer, the structural formula of the fluorine-containing polymer being as follows:

CF₂(CF₃)CF₂—[O—CF(CF₃)CF₂]ₙ—O—CF(CF₃)COO—R
where n in the range of 1-8, and R is one or more of H and NH₄; and
based on the weight of the fluorine-containing composition, the content a of the fluorine-containing polymer with n being 1 is 0-10 wt %, the content b of the fluorine-containing polymer with n being 2 is 30-68 wt %, the content c of the fluorine-containing polymer with n being 3 is 32-60 wt %, the content d of the fluorine-containing polymer with n being 4 is 0-15 wt %, the content e of the fluorine-containing polymer with n≥5 is 0-8 wt %, and the content b+the content c≥80 wt %, the content a, the content d and the content e are 0 at the same time, or either one is 0, or not 0 at the same time;

B) water-soluble resin; C) an alkali; D) an acid; and E) a surfactant.

Based on the weight, the composition for preparing a top antireflection film contains 1-15 wt % of fluorine-containing composition, preferably 1.5-12 wt % of fluorine-containing composition, more preferably 1.5-8 wt % of fluorine-containing composition.

After in-depth research, it is found that when the composition according to the present application meets the above conditions, the composition solution has good stability and film-forming property, and can be coated with less amount to form an antireflection film having equivalent performances to the antireflection film in the prior art, the refractive index of the antireflection film at 248 nm is 1.41-1.44, which can effectively reduce the refractive index under laser irradiation with the wavelength of 248 nm, and can be used as a top antireflection film for photoresist.

After in-depth research, it is found that when the content a is greater than 10 wt %, the film-forming property of the composition is not good, and holes are prone to appear on the surface of the film; when the content e is greater than 8 wt %, the film-forming property of the composition is not good, the film formed is unevenly distributed, and holes are prone to appear on the surface of the film; and when the content d is greater than 15 wt %, the film-forming property of the composition is usually not good, the film formed is unevenly distributed, and holes are prone to appear on the surface of the film.

Furthermore, the applicant finds that the photochemical reaction occurs in the part of the photoresist irradiated by the specific light source, and the production of H+ reduces the pH of the photoresist in the irradiated part to 1.5-2.5, when the pH value of the top antireflection layer is large, the baking process is carried out after photolithography, H+ may diffuse to the junction area of the top antireflection layer and the photoresist, and the pH of this area rises, and the development process cannot be fully removed by the developing solution, thereby forming the T-shaped top. Adding an appropriate amount of acid to the top antireflection layer system can inhibit the diffusion of H+ to the antireflection film in the photoresist and avoid the formation of the T-shaped top. With the increase of macromolecular polymers of the content c (pentamer), it helps to improve the strength of the antireflection film body and the affinity with the photoresist layer, and when the content c (pentamer) is greater than 30 wt %, the diffusion of H+ to the antireflection film is intensified, so it is necessary to add an appropriate amount of acids to adjust the pH value and inhibit the diffusion of H+ to the antireflection film in the photoresist.

When the content c (pentamer) is greater than 60 wt %, the uniform and non-porous film can be formed, but a large coating amount is required. When the content b (tetramer) is less than 30 wt %, the uniform and non-porous film can be formed, but a large coating amount is required. Furthermore, if the composition does not contain the surfactant, the uniform and non-porous film can be formed, but a large coating amount is required, and the solution is unstable and prone to precipitate. When the composition does not contain acid, the pH value of the composition is too high, so that the phenomenon that the photoresist produces the T-shaped top is caused during the photolithography using the top antireflection film prepared by it.

Furthermore, the number-average molecular weight of the fluorine-containing polymer is between 600 and 1300, more preferably between 650 and 1100, and the composition for preparing the top antireflection film for photoresist has the viscosity of 1.3-1.5 cp at 25° C.

Furthermore, the content a is 0-9 wt %, preferably 0-8 wt %, more preferably 2-8 wt %. The content b is 35-68 wt %, preferably 35-65 wt %. The content c is 35-55 wt %, preferably 35-50 wt %. The content d is 3-15 wt %, preferably 5-15 wt %. The content e is 0-6 wt %, preferably 0-4 wt %.

The fluorine-containing polymer may polymerize hexafluoropropylene oxide by photooxidation, catalytic oligomerization, plasma or anionic polymerization methods, and then form a corresponding fluorine-containing polymer containing carboxylic acid groups, amine groups and ester groups by reaction with water, amines and ester compounds, respectively.

Furthermore, the molar ratio of the fluorine-containing polymer to the water-soluble resin is 1:2-1:30, preferably 1:3-1:25.

The water-soluble resin is one of or the mixture of polyvinylpyrrolidones, polyacrylic acids, polyurethanes, fluorine-containing polyvinylpyrrolidones, fluorine-containing polyacrylic acids, and fluorine-containing polyurethanes. The water-soluble resin may be one or more of polyvinylpyrrolidones, polyacrylic acids and polyurethanes, or the water-soluble resin obtained by substituting all or part of the hydrogen atoms of the alkyl group of the water-soluble resin by fluorine atoms. The number-average molecular weight of the water-soluble resin is 3000-30000, preferably, 4000-26000, more preferably 6000-22000.

The polyvinylpyrrolidones can be polyvinylpyrrolidone, or the polymer of polyvinylpyrrolidone and other monomers, and the polyvinylpyrrolidones can be used alone or in combination.

The polyacrylic acids can be polyacrylic acid, or the polymer of polyacrylic acid and other monomers, and the polyacrylic acids can be used alone or in combination.

The polyurethanes can be polyurethane, or the polymer of polyurethane and other monomers, and the polyurethanes can be used alone or in combination.

Furthermore, the alkali can be one or more of ammonium hydroxide, tetramethylammonium hydroxide, alkanolamine, arylamine, alkylamine and the like, preferably tetramethylammonium hydroxide. Based on the total weight of the composition for preparing the top antireflection film, the content of the tetramethylammonium hydroxide is 0.2-2 wt %, preferably 0.2-1 wt %.

Furthermore, the acid may be an organic acid or an inorganic acid or an amino acid. The inorganic acid is preferably hydrochloric acid, sulfuric acid, nitric acid, phosphoric acid, and hydrofluoric acid. The organic acid is preferably oxalic acid, citric acid, alkyl sulfonic acid, alkyl carboxylic acid, alkyl benzenesulfonic acid, alkyl benzenecarboxylic acid, and alkyl sulfonic acid, alkyl carboxylic acid, alkyl benzenesulfonic acid and alkyl benzenecarboxylic acid obtained by substituting all or part of the hydrogen atoms in the alkyl group by fluorine atoms, and the number of carbon atoms contained in the alkyl group ranges from 1-20, preferably 3-15. The amino acid is preferably aminoacetic acid, alanine, valine, leucine, isoleucine, proline, phenylalanine, tryptophan, methionine, serine, threonine, γ-aminobutyl acid, β-cyanine alanine, aspartic acid, etc.

Based on the total weight of the composition for preparing the top antireflection film, the content of the acid is 0.3-5 wt %, preferably 0.5-3 wt %.

Furthermore, the surfactant is isopropanol, hexafluoroisopropanol, methanol, dodecyl carboxylic acid, dodecylbenzene sulfonic acid, etc., and based on the total weight of the composition for preparing the top antireflection film for photoresist, the content of the surfactant is 0.1-5 wt %, preferably 0.3-4 wt %.

Furthermore, the composition for preparing the top antireflection film further includes water and/or water-soluble organic solvent. The water-soluble organic solvent may be alcohols, ketones or esters. Preferably, the water-soluble organic solvent is methanol, ethanol, isopropanol, acetone, methyl acetate, ethyl acetate, ethyl lactate, dimethylformamide, or dimethyl sulfoxide.

The present invention also provides the top antireflection film for photoresist, which is prepared from any fluorine-containing composition for preparing the top antireflection film.

The present invention also provides the fluorine-containing composition which contains the fluorine-containing polymer, the structural formula of the fluorine-containing polymer being as follows:

CF₂(CF₃)CF₂—[O—CF(CF₃)CF₂]ₙ—O—CF(CF₃)COO—R
where n in the range of 1-8, and R is one or more of H and NH₄; and
based on the weight of the fluorine-containing composition, the content a of the fluorine-containing polymer with n being 1 is 0-10 wt %, the content b of the fluorine-containing polymer with n being 2 is 30-68 wt %, the content c of the fluorine-containing polymer with n being 3 is 32-60 wt %, the content d of the fluorine-containing polymer with n being 4 is 0-15 wt %, the content e of the fluorine-containing polymer with n≥5 is 0-8 wt %, and the content b+the content c≥80 wt %, the content a, the content d and the content e are 0 at the same time, or either one is 0, or not 0 at the same time.

Beneficial Effects

The present invention obtains the fluorine-containing composition meeting the specific composition requirements of the present invention by controlling the synthetic degree of polymerization of fluorine-containing polymer and the content distribution of fluorine-containing polymer components in the fluorine-containing composition. The fluorine-containing composition is easy to produce, lower in the raw material cost, easy to degrade, low toxicity, and environmentally friendly, the composition solution for preparing the top antireflection film prepared by it has good solution stability and film-forming property, and the refractive index of the antireflection film prepared by it is 1.41-1.44 under the light source of 248 nm, reducing the amount used without atomization and avoiding light scattering and standing wave effect. Moreover, the composition for preparing the top antireflection film has the pH matching the pH of the photoresist, and can be used as the top antireflection film for photoresist to reduce the standing wave effect in the photolithography process. The composition for preparing the top antireflection film also reduces the surface porosity by adding the preferred surfactant, improves the surface porosity and uniformity, while improving the problem of a large difference in thickness between the center point and the edge after coating, improving the yield of the photolithographic process.

### BRIEF DESCRIPTION OF THE DRAWINGS

FIG. 1a shows the photograph of the solution condition of the composition solution of Example 1 on day 1;

FIG. 1b shows the photograph of the solution condition of the composition solution of Example 1 on day 14;

FIG. 1c shows the photograph of the solution condition of the composition solution of Comparative Example 7 on day 3;

FIG. 1d shows the photograph of the solution condition of the composition solution of Comparative Example 7 on day 14;

FIG. 2 shows the microphotograph of the film formed by the composition of Example 1;

FIG. 3 shows the microphotograph of the film formed by the composition of Example 2;

FIG. 4 shows the microphotograph of the film formed by the composition of Comparative Example 1;

FIG. 5 shows the microphotograph of the film formed by the composition of Comparative Example 4;

FIG. 6 shows the microphotograph of the film formed by the composition of Comparative Example 5;

FIG. 7 shows the photoresist pattern formed by applying the top antireflection film prepared by the composition of Example 1 to the photolithographic process;

FIG. 8 shows the photoresist pattern formed by applying the top antireflection film prepared by the composition of Comparative Example 6 to the photolithographic process;

FIG. 9a shows the SEM picture of the thickness of the center point measured by the top antireflection film prepared by the sample of Example 1;

FIG. 9b shows the SEM picture of the thickness of the edge point measured by the top antireflection film prepared by the sample of Example 1;

FIG. 10a shows the SEM picture of the thickness of the center point measured by the top antireflection film prepared by the sample of Comparative Example 9; and

FIG. 10b shows the SEM picture of the thickness of the edge point measured by the top antireflection film prepared by the sample of Comparative Example 9.

### DESCRIPTION OF EMBODIMENTS

The present invention will now be discussed with reference to a number of exemplary embodiments. It is to be understood that these embodiments are discussed only to enable those of ordinary skill in the art to better understand and thus realize the content of the present invention, rather than implying any limitation of the scope of the present invention.

As used herein, the term “including” and variants thereof are to be construed as an open term meaning “including but not limited to”. The term “based on” is to be construed as “based at least in part on”. The terms “one example” and “an example” are to be construed as “at least one example”. The term “another example” is to be construed as “at least one other example”.

The present embodiment discloses the fluorine-containing polymer for preparing the top antireflection film—the perfluoropolyethercarboxylic acid preparation method:

### Preparation of Perfluoropolyethercarboxylic Acid

(1) first adding the solution containing 50 ml of acetonitrile and 50 ml of tetraethylene glycol dimethyl ether to 1 L of polymerization kettle, and then adding 5 g of catalyst KF into the polymerization kettle, after stirring and mixing evenly, replacing with high-purity nitrogen three times, pumping the negative pressure to −0.1 MPa, cooling to the set temperature 0° C., introducing 50 g of hexafluoropropylene oxide, controlling the reaction process by using timed feeding (50 g/h), controlling the temperature between 0 and 10° C.; after adding hexafluoropropylene oxide to 1000 g, returning to normal pressure, completing the reaction, keeping stirring for two hours, stopping stirring, and returning to room temperature to obtain the mixture;
(2) layering the mixture, centrifuging and filtering the lower product to separate the reaction product I, adding the reaction product I to the distillation apparatus, and obtaining perfluoropolyetheryl fluoride with the purity of more than 99% (the purity tested by the gas chromatograph) through distillation purification; and
(3) adding the perfluoropolyetheryl fluoride to 1 L of acid kettle, adding water according to the volume ratio of perfluoropolyetheryl fluoride to water of 1:3, heating and refluxing for four hours, continuing to heat up to 90° C., after demulsification, standing dispersion to remove the upper water, repeating the demulsification and standing dispersion twice, raising the temperature to 110° C., and removing the residual water and hydrogen fluoride to obtain the perfluoropolyethercarboxylic acid.

By controlling the degree of polymerization of the perfluoropolyetheryl fluoride, the following perfluoropolyethercarboxylic acid with the following general formula structure is obtained:

CF₂(CF₃)CF₂—[O—CF(CF₃)CF₂]ₙ—O—CF(CF₃)COOH

Based on the weight of the whole polymer, the content a of perfluoropolyethercarboxylic acid A with n being 1 is 0-10 wt %, the content b of perfluoropolyethercarboxylic acid B with n being 2 is 30-68 wt %, the content c of perfluoropolyethercarboxylic acid C with n being 3 is 32-60 wt %, the content d of perfluoropolyethercarboxylic acid D with n being 4 is 0-15 wt %, the perfluoropolyethercarboxylic acid with n≥5 includes perfluoropolyethercarboxylic acid E with n being 5 and perfluoropolyethercarboxylic acid F with n being 8, the total content e of the perfluoropolyethercarboxylic acid E and the perfluoropolyethercarboxylic acid F is 0-8 wt %, and the content b+the content c≥80 wt %, the content a, the content d and the content e are 0 at the same time, or either one is 0, or not 0 at the same time.

### Example 1

The perfluoropolyethercarboxylic acids of different degrees of polymerization described above are mixed in the following proportions: based on the weight, 4 wt % of perfluoropolyethercarboxylic acid A, 55 wt % of perfluoropolyethercarboxylic acid B, 38 wt % of perfluoropolyethercarboxylic acid C, and 3 wt % of perfluoropolyethercarboxylic acid D, to prepare the perfluoropolyethercarboxylic acid composition, and the specific components thereof are as shown in Table 1.

0.0064 moles of perfluoropolyethercarboxylic acid is prepared into 2 wt % of aqueous solution, and then mixed with 2 wt % of polyvinylpyrrolidone aqueous solution in the molar ratio of perfluoropolyethercarboxylic acid to polyvinylpyrrolidone of 10:1, and stirred until the transparent solution is obtained. Under stirring conditions, 2 wt % of tetramethylammonium hydroxide solution is added to the solution, and the usage amount of tetramethylammonium hydroxide is 0.584 g; then, 1.32 g of surfactant isopropanol is added, 2.0 g of oxalic acid is added, and the pH value is adjusted to 2.0-2.5; and filtration is filtered to obtain the composition solution.

It has been calculated that based on the weight, the components of the composition solution are 1.727 wt % of perfluoropolyethercarboxylic acid composition, 0.027 wt % of polyvinylpyrrolidone, 0.221 wt % of tetramethylammonium hydroxide, 0.499 wt % of isopropanol, 0.756 wt % of oxalic acid, and 96.77 wt % of water.

### Example 2

The perfluoropolyethercarboxylic acids of different degrees of polymerization described above are mixed in the following proportions: based on the weight, 2 wt % of perfluoropolyethercarboxylic acid A, 40 wt % of perfluoropolyethercarboxylic acid B, 48 wt % of perfluoropolyethercarboxylic acid C, and 10 wt % of perfluoropolyethercarboxylic acid D, to prepare the perfluoropolyethercarboxylic acid composition, and the specific components thereof are as shown in Table 1.

In addition to substituting isopropanol by 1.32 g of surfactant hexafluoroisopropanol, the compositional solution is obtained in the same manner as Example 1. Based on the weight, the components of the composition solution are 1.74 wt % of perfluoropolyethercarboxylic acid composition, 0.026 wt % of polyvinylpyrrolidone, 0.21 wt % of tetramethylammonium hydroxide, 0.475 wt % of hexafluoroisopropanol, 0.72 wt % of oxalic acid, and 96.829 wt % of water.

### Example 3

The perfluoropolyethercarboxylic acids of different degrees of polymerization described above are mixed in the following proportions: based on the weight, 8 wt % of perfluoropolyethercarboxylic acid A, 54 wt % of perfluoropolyethercarboxylic acid B, 36 wt % of perfluoropolyethercarboxylic acid C, 1 wt % of perfluoropolyethercarboxylic acid E, and 1 wt % of perfluoropolyethercarboxylic acid F, to prepare the perfluoropolyethercarboxylic acid composition, and the specific components thereof are as shown in Table 1.

In addition to substituting polyvinylpyrrolidone by 0.11 g of polyacrylic acid and substituting isopropanol by the surfactant methanol, the composition solution is obtained in the same manner as Example 1. The polyacrylic acid is Mw=3000, 50 wt % aqueous solution.

Based on the weight, the components of the composition solution are 1.709 wt % of perfluoropolyethercarboxylic acid composition, 0.042 wt % of polyacrylic acid, 0.223 wt % of tetramethylammonium hydroxide, 0.504 wt % of methanol, 0.764 wt % of oxalic acid, and 96.758 wt % of water.

### Example 4

The perfluoropolyethercarboxylic acids of different degrees of polymerization described above are mixed in the following proportions: based on the weight, 2 wt % of perfluoropolyethercarboxylic acid A, 32 wt % of perfluoropolyethercarboxylic acid B, 58 wt % of perfluoropolyethercarboxylic acid C, 2 wt % of perfluoropolyethercarboxylic acid D, and 6 wt % of perfluoropolyethercarboxylic acid E, to prepare the perfluoropolyethercarboxylic acid composition, and the specific components thereof are as shown in Table 1.

In addition to substituting oxalic acid by citric acid and substituting isopropanol by the surfactant Dodecylcarboxylic acid, the compositional solution is obtained in the same manner as Example 1.

Based on the weight, the components of the composition solution are 1.750 wt % of perfluoropolyethercarboxylic acid composition, 0.024 wt % of polyvinylpyrrolidone, 0.201 wt % of tetramethylammonium hydroxide, 0.455 wt % of dodecylcarboxylic acid, 0.690 wt % of citric acid, and 96.880 wt % of water.

### Example 5

The perfluoropolyethercarboxylic acids of different degrees of polymerization described above are mixed in the following proportions: based on the weight, 61 wt % of perfluoropolyethercarboxylic acid B, 37 wt % of perfluoropolyethercarboxylic acid C, and 2 wt % of perfluoropolyethercarboxylic acid D, to prepare the perfluoropolyethercarboxylic acid composition, and the specific components thereof are as shown in Table 1.

In addition to substituting isopropanol by hexafluoroisopropanol, the compositional solution is obtained in the same manner as Example 1.

Based on the weight, the components of the composition solution are 1.729 wt % of perfluoropolyethercarboxylic acid composition, 0.027 wt % of polyvinylpyrrolidone, 0.219 wt % of tetramethylammonium hydroxide, 0.495 wt % of hexafluoroisopropanol, 0.75 wt % of oxalic acid, and 96.78 wt % of water.

### Example 6

The perfluoropolyethercarboxylic acids of different degrees of polymerization described above are mixed in the following proportions: based on the weight, 2 wt % of perfluoropolyethercarboxylic acid A, 65 wt % of perfluoropolyethercarboxylic acid B, 32 wt % of perfluoropolyethercarboxylic acid C, and 1 wt % of perfluoropolyethercarboxylic acid D, to prepare the perfluoropolyethercarboxylic acid composition, and the specific components thereof are as shown in Table 1.

In addition to substituting oxalic acid by perfluorohexylsulfonic acid, the compositional solution is obtained in the same manner as Example 1.

Based on the weight, the components of the composition solution are 1.725 wt % of perfluoropolyethercarboxylic acid composition, 0.027 wt % of polyvinylpyrrolidone, 0.223 wt % of tetramethylammonium hydroxide, 0.504 wt % of isopropanol, 0.763 wt % of perfluorohexylsulfonic acid, and 96.758 wt % of water.

### Example 7

The perfluoropolyethercarboxylic acids of different degrees of polymerization described above are mixed in the following proportions: based on the weight, 52 wt % of perfluoropolyethercarboxylic acid B and 48 wt % of perfluoropolyethercarboxylic acid C, to prepare the perfluoropolyethercarboxylic acid composition, and the specific components thereof are as shown in Table 1.

In addition to substituting oxalic acid by aminoacetic acid, the compositional solution is obtained in the same manner as Example 1.

Based on the weight, the components of the composition solution are 1.733 wt % of perfluoropolyethercarboxylic acid composition, 0.026 wt % of polyvinylpyrrolidone, 0.216 wt % of tetramethylammonium hydroxide, 0.488 wt % of isopropanol, 0.74 wt % of aminoacetic acid, and 96.797 wt % of water.

### Comparative Example 1

The compositional solution is obtained in the same manner as Example 1, and the following perfluoropolyethercarboxylic acid is used.

The perfluoropolyethercarboxylic acids of different degrees of polymerization described above are mixed in the following proportions: based on the weight, 11 wt % of perfluoropolyethercarboxylic acid A, 48 wt % of perfluoropolyethercarboxylic acid B, 38 wt % of perfluoropolyethercarboxylic acid C, and 3 wt % of perfluoropolyethercarboxylic acid D, to prepare the perfluoropolyethercarboxylic acid composition, and the specific components thereof are as shown in Table 2.

### Comparative Example 2

The compositional solution is obtained in the same manner as Example 1, and the following perfluoropolyethercarboxylic acid is used.

The perfluoropolyethercarboxylic acids of different degrees of polymerization described above are mixed in the following proportions: based on the weight, 4 wt % of perfluoropolyethercarboxylic acid A, 28 wt % of perfluoropolyethercarboxylic acid B, 56 wt % of perfluoropolyethercarboxylic acid C, and 12 wt % of perfluoropolyethercarboxylic acid D, to prepare the perfluoropolyethercarboxylic acid composition, and the specific components thereof are as shown in Table 2.

### Comparative Example 3

The compositional solution is obtained in the same manner as Example 1, and the following perfluoropolyethercarboxylic acid is used.

The perfluoropolyethercarboxylic acids of different degrees of polymerization described above are mixed in the following proportions: based on the weight, 4 wt % of perfluoropolyethercarboxylic acid A, 32 wt % of perfluoropolyethercarboxylic acid B, 61 wt % of perfluoropolyethercarboxylic acid C, and 3 wt % of perfluoropolyethercarboxylic acid D, to prepare the perfluoropolyethercarboxylic acid composition, and the specific components thereof are as shown in Table 2.

### Comparative Example 4

The compositional solution is obtained in the same manner as Example 1, and the following perfluoropolyethercarboxylic acid is used.

The perfluoropolyethercarboxylic acids of different degrees of polymerization described above are mixed in the following proportions: based on the weight, 4 wt % of perfluoropolyethercarboxylic acid A, 42 wt % of perfluoropolyethercarboxylic acid B, 38 wt % of perfluoropolyethercarboxylic acid C, and 16 wt % of perfluoropolyethercarboxylic acid D, to prepare the perfluoropolyethercarboxylic acid composition, and the specific components thereof are as shown in Table 2.

### Comparative Example 5

The compositional solution is obtained in the same manner as Example 1, and the following perfluoropolyethercarboxylic acid is used.

The perfluoropolyethercarboxylic acids of different degrees of polymerization described above are mixed in the following proportions: based on the weight, 4 wt % of perfluoropolyethercarboxylic acid A, 46 wt % of perfluoropolyethercarboxylic acid B, 38 wt % of perfluoropolyethercarboxylic acid C, 3 wt % of perfluoropolyethercarboxylic acid D, and 9 wt % of perfluoropolyethercarboxylic acid E, to prepare the perfluoropolyethercarboxylic acid composition, and the specific components thereof are as shown in Table 2.

### Comparative Example 6

The compositional solution is obtained in the same manner as Example 1, but oxalic acid is not used. The perfluoropolyethercarboxylic acids of different degrees of polymerization described above are mixed in the following proportions: based on the weight, 4 wt % of perfluoropolyethercarboxylic acid A, 55 wt % of perfluoropolyethercarboxylic acid B, 38 wt % of perfluoropolyethercarboxylic acid C, and 3 wt % of perfluoropolyethercarboxylic acid D, to prepare the perfluoropolyethercarboxylic acid composition, and the specific components thereof are as shown in Table 2.

### Comparative Example 7

The compositional solution is obtained in the same manner as Example 1, but the surfactant isopropanol is not used.

The solution stability, film-forming property, minimum coating amount and refractive index of each prepared composition and the applicability of the prepared top antireflection film in the photolithographic process are evaluated by using the following method, and the results are shown in Table 2 and the drawings.

### Comparative Example 8

The proportions of patent CN112034683B are used, and no surfactant and organic acid are added. The perfluoropolyethercarboxylic acids of different degrees of polymerization prepared by the method disclosed above are mixed in the following proportions: based on the weight, 10 wt % of perfluoropolyethercarboxylic acid A, 66 wt % of perfluoropolyethercarboxylic acid B, 19 wt % of perfluoropolyethercarboxylic acid C, 1 wt % of perfluoropolyethercarboxylic acid D, and 4 wt % of perfluoropolyethercarboxylic acid E, to prepare the perfluoropolyethercarboxylic acid composition, and the specific components thereof are as shown in Table 2.

The solution stability, film-forming property, minimum coating amount and refractive index of each prepared composition and the applicability of the prepared top antireflection film in the photolithographic process are evaluated by using the following method, and the results are shown in Table 2 and the drawings.

### Comparative Example 9

The proportions of patent CN112034683B are used, and no surfactant and organic acid are added. The perfluoropolyethercarboxylic acids of different degrees of polymerization prepared by the method disclosed above are mixed in the following proportions: based on the weight, 4 wt % of perfluoropolyethercarboxylic acid A, 58 wt % of perfluoropolyethercarboxylic acid B, 28 wt % of perfluoropolyethercarboxylic acid C, 8 wt % of perfluoropolyethercarboxylic acid D, and 2 wt % of perfluoropolyethercarboxylic acid E, to prepare the perfluoropolyethercarboxylic acid composition, and the specific components thereof are as shown in Table 2.

The solution stability, film-forming, minimum coating amount and refractive index of each prepared composition and the applicability of the prepared top antireflection film in the photolithographic process are evaluated by using the following method, and the results are shown in Table 2 and the drawings.

### Comparative Example 10

The proportions of Example 4 of patent CN112034683B are used, and no surfactant and organic acid are added. The perfluoropolyethercarboxylic acids of different degrees of polymerization prepared by the method disclosed above are mixed in the following proportions: based on the weight, 4 wt % of perfluoropolyethercarboxylic acid A, 58 wt % of perfluoropolyethercarboxylic acid B, 32 wt % of perfluoropolyethercarboxylic acid C, 4 wt % of perfluoropolyethercarboxylic acid D, and 2 wt % of perfluoropolyethercarboxylic acid E, to prepare the perfluoropolyethercarboxylic acid composition, and the specific components thereof are as shown in Table 2.

The solution stability, film-forming, minimum coating amount and refractive index of each prepared composition and the applicability of the prepared top antireflection film in the photolithographic process are evaluated by using the following method, and the results are shown in Table 2 and the drawings.

### Comparative Example 11

The proportions of Example 4 of patent CN112034683B are used, and no surfactant isopropanol and oxalic acid are added. The perfluoropolyethercarboxylic acids of different degrees of polymerization prepared by the method disclosed above are mixed in the following proportions: based on the weight, 4 wt % of perfluoropolyethercarboxylic acid A, 58 wt % of perfluoropolyethercarboxylic acid B, 32 wt % of perfluoropolyethercarboxylic acid C, 4 wt % of perfluoropolyethercarboxylic acid D, and 2 wt % of perfluoropolyethercarboxylic acid E, to prepare the perfluoropolyethercarboxylic acid composition, and the specific components thereof are as shown in Table 2.

The solution stability, film-forming property, minimum coating amount and refractive index of each prepared composition and the applicability of the prepared top antireflection film in the photolithographic process are evaluated by using the following method, and the results are shown in Table 2 and the drawings.

Method for measuring number-average molecular weight

The number-average molecular weight of the perfluoropolyethercarboxylic acid is measured by an acid number method:
transferring 1 ml of perfluoropolyethercarboxylic acid to be measured, weighing record data m(g), adding 35 ml of water and 15 ml of absolute ethanol, titrating the sodium hydroxide solution at the calibrated concentration c (mol/ml), and recording the volume v (ml) of sodium hydroxide consumed when titrated to pH=7. The number-average molecular weight of the perfluoropolyethercarboxylic acid is calculated according to the following formula:
the number-average molecular weight of the perfluoropolyethercarboxylic acid=m/cv.

Solution Stability Evaluation Method
placing 250 ml of the prepared composition solution for preparing an antireflection film in 500 ml of beaker, standing, visually observing the condition of the solution, and recording the time of the occurrence of precipitated flocculent as the stability time h (in days) to evaluate its stability, where 14 days is the observation deadline. The larger the h value is, the better the solution stability is.

Film-Forming Property Evaluation Method
coating the silicon wafer (4 inches, doped with boron, the thickness is about 525 m, and the diameter is about 100 mm) with the composition solution for preparing an antireflection film by using the rotary coating machine, baking at 100° C. for 90 seconds, and forming the corresponding film after cooling; visually observing the condition of the formed film, and performing microscopic observation by means of the metallographic microscope, and taking the microphotograph to evaluate the film-forming property of the composition.

Minimum Coating Amount Evaluation Method
coating the silicon wafer with the positive photoresist by using the rotary coating machine, and then prebaking on the hot plate of 130° C. for 60 seconds to form photoresist film with the thickness of 800 nm on the silicon wafer; measuring the film thickness with the film thickness measuring device; subsequently, coating the photoresist film with the composition for forming an antireflection film by using the same rotary coating machine mentioned above, and prebaking on the hot plate of 90° C. for 60 seconds to form an antireflection film with the film thickness of 45 nm on the photoresist film, where through visual observation, the coated antireflection film composition may cover the edge portion of the photoresist film and form the minimum usage amount of the evenly coated film, which is recorded as the minimum coating amount for forming the antireflection film, and the results are shown in Tables 1 and 2.

Refractive Index Measuring Method
coating the silicon wafer (4 inches, doped with boron, the thickness is about 525 m, and the diameter is about 100 mm) with the composition solution for preparing an antireflection film by using the rotary coating machine, baking at 100° C. for 90 seconds, and forming the coating after cooling; and testing with an ellipsometer to determine the refractive index at 248 nm.

Viscosity Measuring Method
using the digital viscometer, first preheating for 20 min, adjusting the base nut so that the instrument is parallel to the ground, installing the rotor and the drum, and then pouring in the measured liquid (using the rotor 0); using the cooling circulating pump to set the temperature to 25° C., connecting the circulating cup, making the water temperature in the circulating cup reach 25° C., completely immersing the drum in water, placing for 20 min to constant temperature, where the speed is 60 r/min, and the rotation time is 10 min; determining the liquid viscosity, measurement is repeated 5 times to obtain an average value, and the results are shown in Tables 1 and 2.

Applicability Evaluation Method in Photolithographic Process
coating the silicon wafer (4 inches, doped with boron, the thickness is about 525 μm, and the diameter is about 100 mm) coated with the photoresist with the composition solution for preparing an antireflection film by using the rotary coating machine, baking at 100° C. for 90 seconds, and forming the coating after cooling as the top antireflection film of the photoresist; exposing the coated sample with the 248 nm lithography machine through the photomask, then baking at 100° C. for 60 seconds, and then developing with 2.38 wt % tetramethylamine hydroxide (TMAH) developing solution for 60 seconds; perfroming freezing microtome section on the developed silicon wafer, and after the section is sprayed with gold, placing under the scanning electron microscope for observation, looking for defects, and taking screenshots to evaluate the effect of the top antireflection film on the photoresist during use.

TABLE 1

| | Perfluoropolyethercarboxylic acid | | | | | | | | | | | |
|---|---|---|---|---|---|---|---|---|---|---|---|---|
| | | | | | | Number- | | | | | | Viscosity |
| | | | | | | average | | | Film- | Minimum | Re- | (25° C., |
| | Content | Content | Content | Content | Content | molecular | | | forming | coating | fractive | 60 rpm, |
| No. | a | b | c | d | e | weight | Acid | Surfactant | property | amount | index | cP) |
| Example | 4% | 55% | 38% | 3% | 0% | 714 | Oxalic | Isopropanol | Uniform | 2.0 ml | 1.42 | 131 |
| 1 | | | | | | | acid | | and non- | | | |
| | | | | | | | | | porous | | | |
| Example | 2% | 40% | 48% | 10% | 0% | 755 | Oxalic | Hexafluoro- | Uniform | 2.2 ml | 1.41 | 137 |
| 2 | | | | | | | acid | isopropanol | and non- | | | |
| | | | | | | | | | porous | | | |
| Example | 8% | 54% | 36% | 1% | 1% | 699 | Oxalic | Methanol | Uniform | 2.0 ml | 1.42 | 1.31 |
| 3 | | | | | | | acid | | and non- | | | |
| | | | | | | | | | porous | | | |
| Example | 2% | 32% | 58% | 2% | 6% | 772 | Citric | Dodecyl- | Uniform | 2.3 ml | 1.44 | 1.41 |
| 4 | | | | | | | acid | carboxylic | and non- | | | |
| | | | | | | | | acid | porous | | | |
| Example | 0% | 61% | 37% | 2% | 0% | 720 | Oxalic | Hexafluoro- | Uniform | 2.0 ml | 1.41 | 132 |
| 5 | | | | | | | acid | isopropanol | and non- | | | |
| | | | | | | | | | porous | | | |
| Example | 2% | 65% | 32% | 0% | 1% | 706 | Perfluoro- | Isopropanol | Uniform | 2.0 ml | 1.41 | 131 |
| 6 | | | | | | | hexyl- | | and non- | | | |
| | | | | | | | sulfonic | | porous | | | |
| | | | | | | | acid | | | | | |
| Example | 0% | 52% | 48% | 0% | 0% | 732 | Amino- | Isopropanol | Uniform | 2.1 ml | 1.42 | 1.35 |
| 7 | | | | | | | acetic | | and non- | | | |
| | | | | | | | acid | | porous | | | |

TABLE 2

| | Perfluoropolyethercarboxylic acid | | | | | | | | | | | |
|---|---|---|---|---|---|---|---|---|---|---|---|---|
| | | | | | | Number- | | | | | | Viscosity |
| | | | | | | average | | | Film- | Minimum | Re- | (25° C., |
| | Content | Content | Content | Content | Content | molecular | | Sur- | forming | coating | fractive | 60 rpm, |
| No. | a | b | c | d | e | weight | Acid | factant | property | amount | index | cP) |
| Com- | 11% | 48% | 38% | 3% | 0% | 711 | Oxalic | Iso- | Uneven | 2.0 ml | 1.42 | 1.32 |
| parative | | | | | | | acid | propanol | and | | | |
| Example 1 | | | | | | | | | porous | | | |
| Com- | 4% | 28% | 56% | 12% | 0% | 769 | Oxalic | Iso- | Uniform | 3.8 ml | 1.44 | 1.92 |
| parative | | | | | | | acid | propanol | and | | | |
| Example 2 | | | | | | | | | non- | | | |
| | | | | | | | | | porous | | | |
| Com- | 4% | 32% | 61% | 3% | 0% | 751 | Oxalic | Iso- | Uniform | 4.5 ml | 141 | 2.35 |
| parative | | | | | | | acid | propanol | and | | | |
| Example 3 | | | | | | | | | non- | | | |
| | | | | | | | | | porous | | | |
| Com- | 4% | 42% | 38% | 16% | 0% | 749 | Oxalic | Iso- | Uneven | 2.0 ml | 1.42 | 1.33 |
| parative | | | | | | | acid | propanol | and | | | |
| Example 4 | | | | | | | | | porous | | | |
| Com- | 4% | 46% | 38% | 3% | 9% | 746 | Oxalic | Iso- | Uneven | 5.0 ml | 1.42 | 2.67 |
| parative | | | | | | | acid | propanol | and | | | |
| Example 5 | | | | | | | | | porous | | | |
| Com- | 4% | 55% | 38% | 3% | 0% | 714 | None | Iso- | Uniform | 2.2 ml | 1.42 | 1.38 |
| parative | | | | | | | | propanol | and | | | |
| Example 6 | | | | | | | | | non- | | | |
| | | | | | | | | | porous | | | |
| Com- | 4% | 55% | 38% | 3% | 0% | 714 | Oxalic | None | Uniform | 5.5 ml | 1.42 | 3.17 |
| parative | | | | | | | acid | | and | | | |
| Example 7 | | | | | | | | | non- | | | |
| | | | | | | | | | porous | | | |
| Com- | 10% | 66% | 19% | 1% | 4% | 702.2 | None | None | Uniform | 2.5 ml | 1.42 | 1.53 |
| parative | | | | | | | | | and | | | |
| Example 8 | | | | | | | | | non- | | | |
| | | | | | | | | | porous | | | |
| Com- | 4% | 58% | 28% | 8% | 2% | 746.4 | None | None | Uniform | 2.5 ml | 1.42 | 1.62 |
| parative | | | | | | | | | and | | | |
| Example 9 | | | | | | | | | non- | | | |
| | | | | | | | | | porous | | | |
| Com- | 4% | 58% | 32% | 4% | 2% | 733.7 | — | — | Uneven | 2.5 ml | 1.42 | 1.65 |
| parative | | | | | | | | | and | | | |
| Example | | | | | | | | | porous | | | |
| 10 | | | | | | | | | | | | |
| Com- | 4% | 58% | 32% | 4% | 2% | 733.7 | Oxalic | Iso- | Uniform | 2.1 ml | 1.42 | 1.33 |
| parative | | | | | | | acid | propanol | and | | | |
| Example | | | | | | | | | non- | | | |
| 11 | | | | | | | | | porous | | | |

Note: 1) The percentages in the table are based on the weight, and the number-average molecular weight refers to the number-average molecular weight of perfluoropolyethercarboxylic acid.
2) The contents a, b, c, d, e are defined in the present application as described in the description, for example, the content a is the content of the perfluoropolyethercarboxylic acid with n being 1.

As can be seen from Table 1, the composition prepared by perfluoropolyethercarboxylic acid, water-soluble resin, acid and surfactant that meets the composition requirements of the present application in Example 1-7 of the present application has good solution stability, and can obtain the surface-uniform and non-porous film with the minimum coating amount of 2.0-2.3 ml, with good film-forming property. At the same time, the refractive index of the prepared antireflection film at 248 nm is 1.41-1.44, which can effectively reduce the refractive index under laser irradiation with the wavelength of 248 nm, and may not cause light scattering and standing wave effects, and can be used as the top antireflection film for photoresist. However, the perfluoropolyethercarboxylic acid in Comparative Example 2 contains 28 wt % of perfluoropolyethercarboxylic acid component with n being 2, that is, the content of component B is less than 30 wt %, resulting in that the minimum coating amount for the composition to obtain the surface-uniform and non-porous film is 3.8 ml. The perfluoropolyethercarboxylic acid of Comparative Example 3 contains 61 wt % of perfluoropolyethercarboxylic acid component with n being 3, that is, the content of component C is greater than 60 wt %, resulting in that the minimum coating amount for the composition to obtain the surface-uniform and non-porous film is 4.5 ml. The composition of Comparative Example 7 does not use the surfactant isopropanol, resulting in that the minimum coating amount for the composition to obtain the surface-uniform and non-porous film is 5.5 ml. Comparative Examples 8 and 9 adopt the proportions of patent CN112034683B, no surfactant and organic acid are added, but the minimum coating amount is 2.5 ml, and the viscosity is significantly greater than that of Examples 1-7. Comparative Example 10 adopts the proportion in Example 4 of patent CN112034683B. Based on the proportion in Example 4 of patent CN112034683B, Comparative Example 11 adds the surfactant isopropanol and oxalic acid.

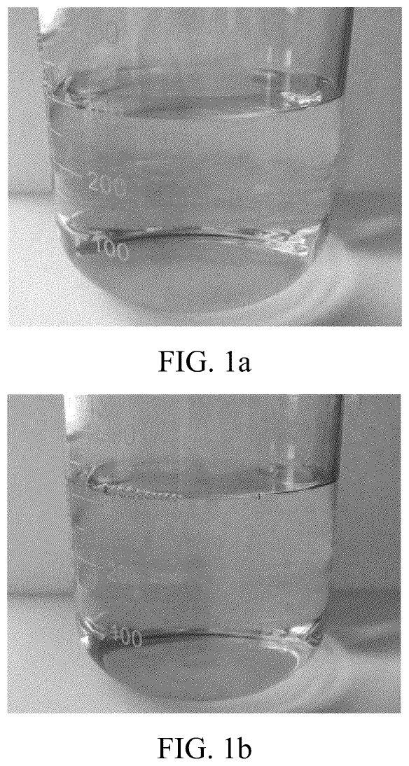

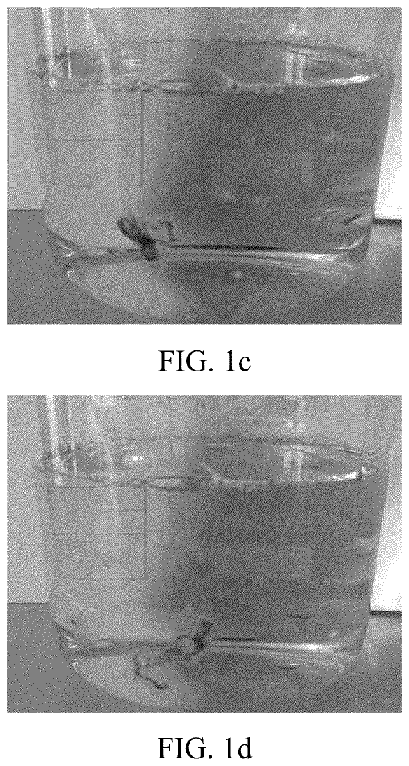

In addition, as can be seen from FIG. 1a, FIG. 1b, FIG. 1c and FIG. 1d, the composition solution meeting the requirements of Example 1 of the present application is left standing for 14 days, still remains clear, does not have precipitated flocculent, and has good solution stability. The composition solution of Comparative Example 7 that does not use the surfactant isopropanol is not stable, the precipitate appears on the third day of standing, and until the 14th day of standing, there is still the significant precipitate in the solution.

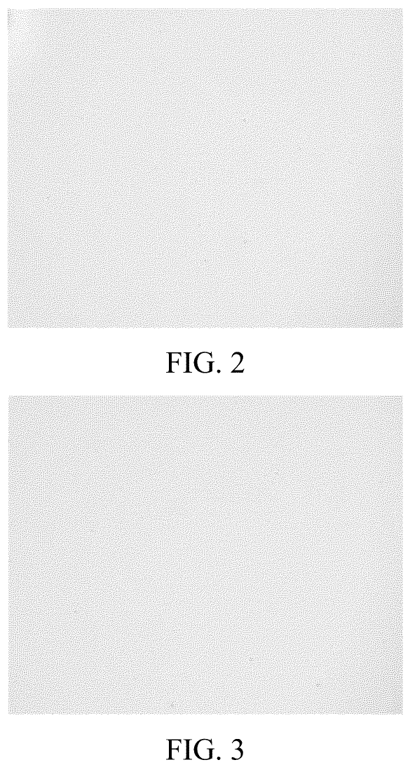

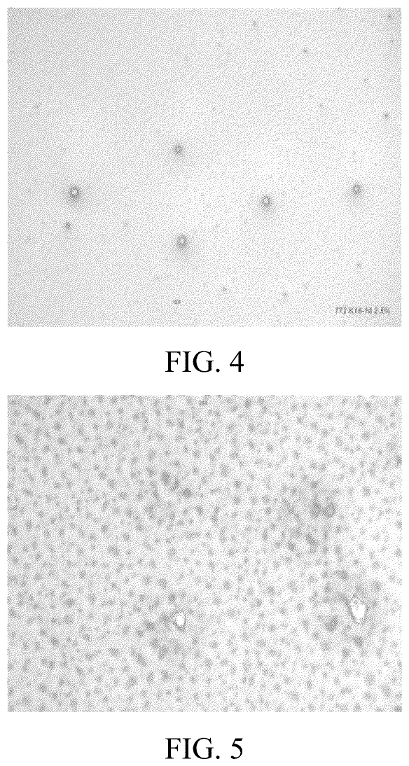

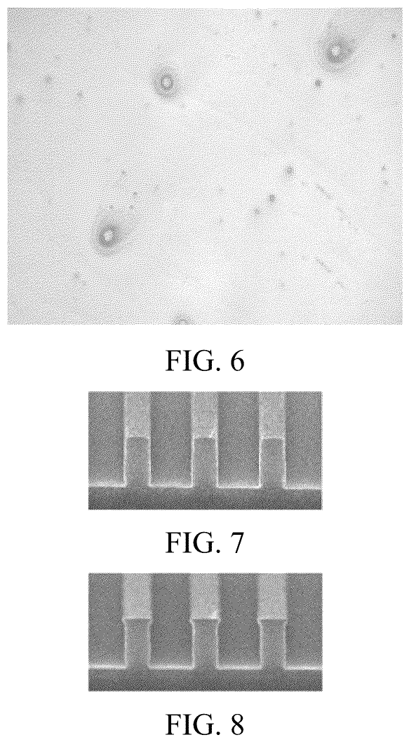

As can be seen from FIG. 2 to FIG. 6, the composition meeting the requirements of Examples 1 and 2 of the present application can obtain the surface-uniform and non-porous film, and has good film-forming property (see FIG. 2 and FIG. 3). The perfluoropolyethercarboxylic acid of Comparative Example 1 contains 11 wt % of perfluoropolyethercarboxylic acid component with n being 1, that is, the content of component A is greater than 10 wt %, resulting in that the film-forming property of the composition prepared is poor, and the formed film has multiple obvious pores (see FIG. 4). The perfluoropolyethercarboxylic acid of Comparative Example 4 contains 16 wt % of perfluoropolyethercarboxylic acid component with n being 4, that is, the content of component D is greater than 15 wt %, resulting in that the film-forming property of the composition prepared is poor, and the formed film is significantly unevenly distributed and has a large number of pores (see FIG. 5). The perfluoropolyethercarboxylic acid of Comparative Example 5 contains 9 wt % of perfluoropolyethercarboxylic acid component with n≥5, that is, the content of component E is greater than 8 wt %, resulting in that the film-forming property of the composition prepared is poor, and the formed film is significantly unevenly distributed and has a large number of pores (see FIG. 6).

As can be seen from FIG. 7 and FIG. 8, the top antireflection film prepared by the composition meeting the requirements of Example 1 of the present application is applied to the photolithographic process, and the pattern of the photoresist formed is normal (see FIG. 7). However, oxalic acid is not used in the composition of Comparative Example 6, the top antireflection film prepared by the composition is applied to the photolithographic process, resulting in the appearance of a T-shaped top in the photoresist (see FIG. 8). This is because a photochemical reaction occurs in the part of the photoresist irradiated by the specific light source, and the production of H+ reduces the pH of the photoresist in the irradiated part to 1.5-2.5, when the pH value of the top antireflection layer is large, the baking process is carried out after photolithography, H+ may diffuse to a junction area of the top antireflection layer and the photoresist, and the pH of this area rises, and the development process cannot be fully removed by the developing solution, thereby forming a T-shaped top. Adding an appropriate amount of acid to the top antireflection layer system can inhibit the diffusion of H+ to the antireflection film in the photoresist and avoid the formation of the T-shaped top.

As can be seen from Comparative Example 10 and Comparative Example 11, the addition of isopropanol and oxalic acid improves the unevenness and multiple pores on the surface of the film layer, and reduces the viscosity and coating amount, because isopropanol plays the solubilizing role, increases the solubility of perfluoropolyetheric acid in water, and optimizes the homogeneity of the formula solution. Moreover, the use of isopropanol reduces the viscosity of the system, making the formulation system easier to homogenize during the mixing process, and the reduction in viscosity also reduces the coating amount.

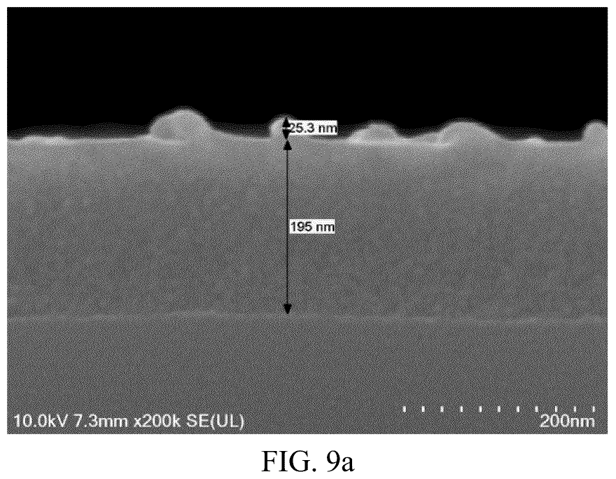

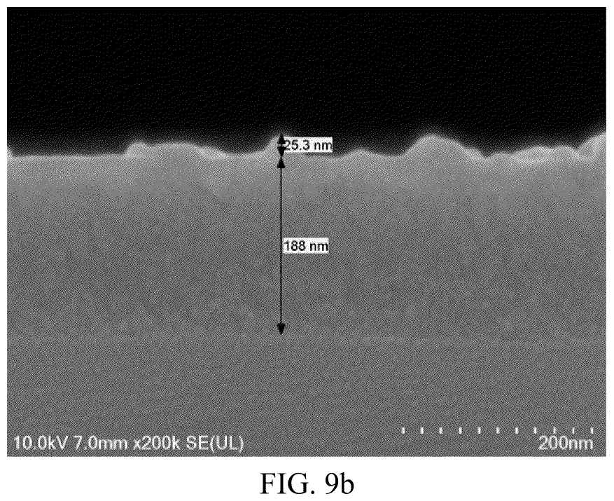

Samples prepared in Example 1 and Comparative Example 9 are selected for coating experiments according to the disclosed minimum coating amount evaluation method, and the thicknesses of the center point and edge point of the composition film layer prepared in Example 1 are as shown in FIG. 9a and FIG. 9b, respectively: both 253 Å.

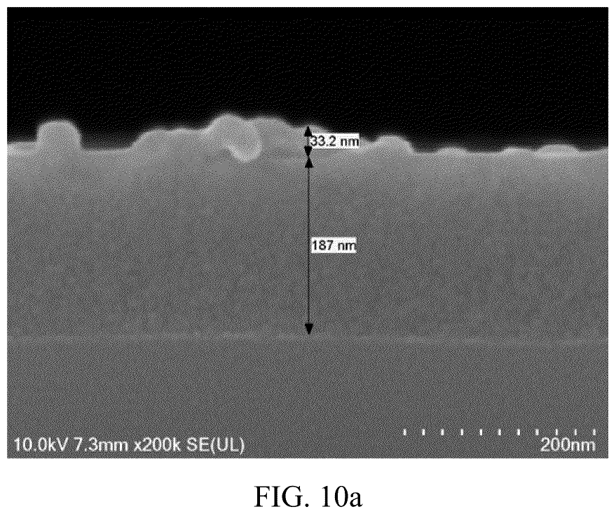

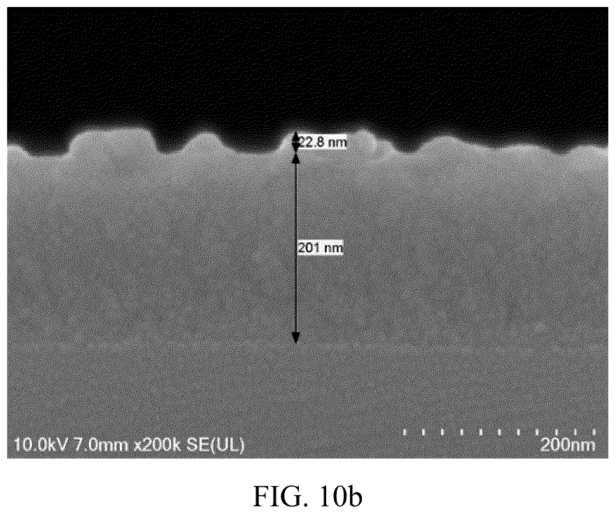

The thicknesses of the center point and edge point of the composition film layer prepared in Comparative Example 9 are as shown in FIG. 10a and FIG. 10b, respectively: 332 Å and 228 Å.

The top antireflection film of the composition of Example 1 has better thickness uniformity at the center point and edge point of the film layer under the same preparation process than Comparative Example 9 using the solution of patent CN112034683B.

In view of the above, according to the solution of the composition of the top antireflection film meeting the requirements of the present application, it has good solution stability, good film-forming property, and can form the uniform antireflection film with the predetermined film thickness on the substrate with the small coating amount, and the refractive index of the antireflection film under the 248 nm light source is 1.41-1.44, which can avoid light scattering and standing wave effects, and can be used as the top antireflection film for the photoresist to form the normal photoresist pattern.

As described in Comparative Examples 1-11, the composition exceeding the requirements of the characterizing features of the present application has the problem of poor solution stability and/or film-forming property, resulting in difficulty in being used as the top antireflection film for the photoresist, or there is the problem of larger minimum coating amount, or the prepared top antireflection film may cause the photoresist to produce the T-shaped top or produce uneven thickness of the center point and edge point of the film layer during the photolithography process.

The use of specific surfactants reduces the viscosity of the system, making it easier to homogenize the formulation system and uniform film thickness during the mixing process, while the reduced viscosity also reduces the coating amount.

Persons of ordinary skill in the art can understand that the foregoing embodiments are specific examples for realizing the present invention. In practical applications, various changes can be made in form and details, without departing from the spirit and the scope of the present invention.

1. A composition for preparing a top antireflection film, comprising:
A) a fluorine-containing composition, the fluorine-containing composition comprising a fluorine-containing polymer, a structural formula of the fluorine-containing polymer being as follows:
CF₂(CF₃)CF₂—[O—CF(CF₃)CF₂]ₙ—O—CF(CF₃)COO—R
wherein n in a range of 1-8, and R is one or more of H and NH₄; and
based on a weight of the fluorine-containing composition, a content a of the fluorine-containing polymer with n being 1 is 0-10 wt %, a content b of the fluorine-containing polymer with n being 2 is 30-68 wt %, a content c of the fluorine-containing polymer with n being 3 is 32-60 wt %, a content d of the fluorine-containing polymer with n being 4 is 0-15 wt %, a content e of the fluorine-containing polymer with n≥5 is 0-8 wt %, and the content b+the content c≥80 wt %, the content a, the content d and the content e are 0 at the same time, or either one is 0, or not 0 at the same time;
B) water-soluble resin; C) an alkali; D) an acid; and E) a surfactant;
wherein the surfactant is one or more of isopropanol, hexafluoroisopropanol, and methanol; a content of the surfactant is 0.1-5 wt %; and based on a total weight of the composition for preparing the top antireflection film, a content of the fluorine-containing composition is 1-15 wt %.

2. The composition for preparing the top antireflection film according to claim 1, wherein the water-soluble resin is a mixture of one or more of polyvinylpyrrolidones, polyacrylic acids, and polyurethanes.

3. The composition for preparing the top antireflection film according to claim 2, wherein the water-soluble resin is a mixture of one or more of fluorine-containing polyvinylpyrrolidones, fluorine-containing polyacrylic acids, and fluorine-containing polyurethanes.

4. The composition for preparing the top antireflection film according to claim 1, wherein a viscosity of the composition for preparing the top antireflection film is 1.3-1.5 cp at 25° C., and a number-average molecular weight of the fluorine-containing polymer is between 600 and 1300.

5. The composition for preparing the top antireflection film according to claim 4, wherein the content a is 0-9 wt %, the content b is 35-68 wt %, the content c is 35-55 wt %, the content d is 3-15 wt %, the content e is 0-6 wt %, and a sum of the content a, the content b, the content c, the content d, and the content e is 100 wt %.

6. The composition for preparing the top antireflection film according to claim 5, wherein the alkali is one or more of ammonium hydroxide, tetramethylammonium hydroxide, alkanolamine, arylamine, and alkylamine; and the content of the alkali is 0.2-2 wt %.

7. The composition for preparing the top antireflection film according to claim 6, wherein the acid is one or more of hydrochloric acid, sulfuric acid, nitric acid, phosphoric acid, hydrofluoric acid, adipic acid, citric acid, alkyl sulfonic acid, alkyl carboxylic acid, alkyl benzenesulfonic acid, alkyl benzenecarboxylic acid, fluorine atom-substituted alkyl sulfonic acid, fluorine atom-substituted alkyl benzenesulfonic acid, fluorine atom-substituted alkyl benzenecarboxylic acid and amino acid; and the content of the acid is 0.3-5 wt %.

8. The composition for preparing the top antireflection film according to claim 7, further comprising water and/or a water-soluble organic solvent, wherein a molar ratio of the fluorine-containing polymer to the water-soluble resin in the composition for preparing the top antireflection film is 1:2-1:30.

9. The composition for preparing the top antireflection film according to claim 8, wherein the molar ratio of the fluorine-containing polymer to the water-soluble resin in the composition for preparing the top antireflection film is 1:3-1:25; and/or the content of the surfactant is 0.3-4 wt %; and/or the content of the acid is 0.5-3 wt %; and/or the content of the alkali is 0.2-1 wt %; and/or the content of the fluorine-containing composition in the composition for preparing the top antireflection film is 1.5-12 wt %; and/or the number-average molecular weight of the fluorine-containing polymer is between 650 and 1100; and/or the content a is 0-8 wt %; and/or the content b is 35-65 wt %; and/or the content c is 35-50 wt %; and/or the content d is 5-15 wt %; and/or the content e is 0-4 wt %; and the sum of the content a, the content b, the content c, the content d, and the content e is 100 wt %.

10. The composition for preparing the top antireflection film according to claim 9, wherein the content of the fluorine-containing composition in the composition for preparing the top antireflection film is 1.5-8 wt %; and/or the content a is 2-8 wt %.

11. A top antireflection film prepared from the composition for preparing the top antireflection film according to claim 1.

12. A fluorine-containing composition for preparing the composition for preparing the top antireflection film according to claim 1, comprising a fluorine-containing polymer, a structural formula of the fluorine-containing polymer being as follows:
CF₂(CF₃)CF₂—[O—CF(CF₃)CF₂]ₙ—O—CF(CF₃)COO—R
wherein n in a range of 1-8, and R is one or more of H and NH₄;
based on a weight of the fluorine-containing composition, a content a of the fluorine-containing polymer with n being 1 is 0-10 wt %, a content b of the fluorine-containing polymer with n being 2 is 30-68 wt %, a content c of the fluorine-containing polymer with n being 3 is 32-60 wt %, a content d of the fluorine-containing polymer with n being 4 is 0-15 wt %, a content e of the fluorine-containing polymer with n≥5 is 0-8 wt %, and the content b+the content c≥80 wt %, the content a, the content d and the content e are 0 at the same time, or either one is 0, or not 0 at the same time.
